(19) United States
(12) Patent Application Publication
(10) Pub. No.: US 2013/0300902 A1
(43) Pub. Date: Nov. 14, 2013

(54) COLOR IMAGE SENSOR PIXEL ARRAY

(71) Applicant: Hiok Nam TAY, Singapore (SG)

(72) Inventor: Hiok Nam TAY, Singapore (SG)

(21) Appl. No.: 13/845,199

(22) Filed: Mar. 18, 2013

Related U.S. Application Data
(60) Provisional application No. 61/617,655, filed on Mar. 29, 2012.

(51) Int. Cl. H01L 27/146; H04N 9/04

(52) U.S. Cl. CPC H01L 27/14625; H04N 9/045
USPC 348/273; 250/208.1

(57) ABSTRACT

An image sensor that has a two-dimensional pixel array consisting of blue, green, and red pixels. The blue pixel comprises a blue color filter, a doped region of a second conductivity type disposed in the substrate and arranged to collect charge carriers generated by photons that enter the substrate from the blue color filter, and a transfer switch connected to transfer charges from the doped region. A trap region of the second conductivity type is buried under the doped region. Charge carriers collected by the trap region during a charge integration period of the doped region are drained to a surface of the substrate. No charges collected by the trap region during the charge integration period is used for generating a color image that is generated using a signal that results from charge carriers collected by the doped region during the charge integration period.

### CROSS-REFERENCE TO RELATED APPLICATIONS

This application claims priority to U.S. Provisional Patent Application No. 61/617,655 filed on Mar. 29, 2012.

### BACKGROUND OF THE INVENTION

1. Field of the Invention

The subject matter disclosed, generally relates to structures and methods for sampling color images on solid state image sensors and reconstructing the color images.

2. Background Information

Photographic equipment such as digital cameras and digital camcorders may contain electronic image sensors that capture light for processing into still or video images. Electronic image sensors typically contain millions of light capturing elements generally known as photoelectric conversion units, such as photodiodes. The elements each receives light that passes through a color filter in a two-dimensional color filter array.

Conventional image sensors suffer from stray charges that diffuse laterally in the substrate across pixels, resulting in blurred images and poor color reproduction. There is a need to reduce the lateral propagation of charges in the substrate.

### BRIEF SUMMARY OF THE INVENTION

According to a first aspect, the present invention relates to an image sensor supported by a substrate of a first conductivity type, comprising a two-dimensional array of a two-by-two subarray of adjacent pixels where the two-by-two subarray comprises a pair of green pixels along a diagonal and a pair of a red pixel and a blue pixel along the other diagonal, where each of the green pixels has a green color filter and a photoelectric conversion unit that receives light from the green color filter, where the red pixel has a red color filter and a photoelectric conversion unit that receives light from the red color filter, and where the blue pixel comprises (a) a blue color filter, (b) a doped region of a second conductivity type in the substrate arranged to collect charge carriers generated by photons that enter the substrate from the blue color filter; (c) a transfer switch connected to transfer charges from the doped region; (d) a trap region of the second conductivity type buried under the doped region, charge carriers collected by the trap region during a charge integration period of the doped region are drained to a surface of the substrate, no charges collected by the trap region during the charge integration period is used for generating a color image that is generated using a signal that results from charge carriers collected by the doped region during the charge integration period.

In the first aspect, it is preferable that a barrier region of the first conductivity type is disposed laterally adjacent to the trap region to stop a depletion region that extends from the trap region.

In the first aspect, it is preferable that a barrier region of the first conductivity type is disposed above the trap region and under the doped region to stop a depletion region that extends from the trap region.

In the first aspect, it is preferable that a relative lateral position of the trap region with respect to the doped region varies between a center region of the pixel array and a corner region of the pixel array.

According to a second aspect, one of the green pixels of the two-by-two subarray of the first aspect is replaced with a white pixel arranged to receive white light.

According to a third aspect, the green pixels of the two-by-two subarray of the first aspect are replaced with the blue pixels and the blue pixel is replaced with the green pixel.

### BRIEF DESCRIPTION OF THE DRAWINGS

FIG. 1 shows an image sensor with a pixel array;

FIG. 2 shows an image capture system that incorporates the image sensor;

FIG. 3 shows a conventional Bayer color filter pattern in which a half of the pixels in a rectangular region are green pixels;

FIG. 4 shows a second color filter pattern that mixes red, green, blue, and white pixels;

FIG. 5 shows a third color filter pattern in which a half of the pixels in a rectangular region are blue pixels;

FIG. 6 shows a cross section of a blue pixel, which includes a substrate, a blue color filter over the substrate, a photoelectric conversion unit in the substrate, and a trap region buried In the substrate and under the photoelectric conversion unit;

FIG. 7 shows a vertical doping profile of the blue pixel;

FIGS. 8A, B and C show different charge-draining circuits connected to a terminal of the trap region;

FIG. 9 shows a cross section of a blue pixel in a corner region of the pixel array;

FIG. 10 shows a processor that performs color interpolation to generate a color image out of the mosaic image received from the pixel array.

### DETAILED DESCRIPTION

Disclosed is a color image sensor that includes a two dimensional pixel array supported by a substrate. The pixel array includes a plurality of pixels to detect visible light of different colors. Each of the plurality of pixels includes a photoelectric conversion unit in the substrate. Light that enters the substrate generate charge carriers that are collected by the photoelectric conversion unit. The pixel array includes a blue pixel that includes a charge trap region under the blue pixel's photoelectric conversion unit. The charge trap region and the substrate belong to opposite conductivity types.

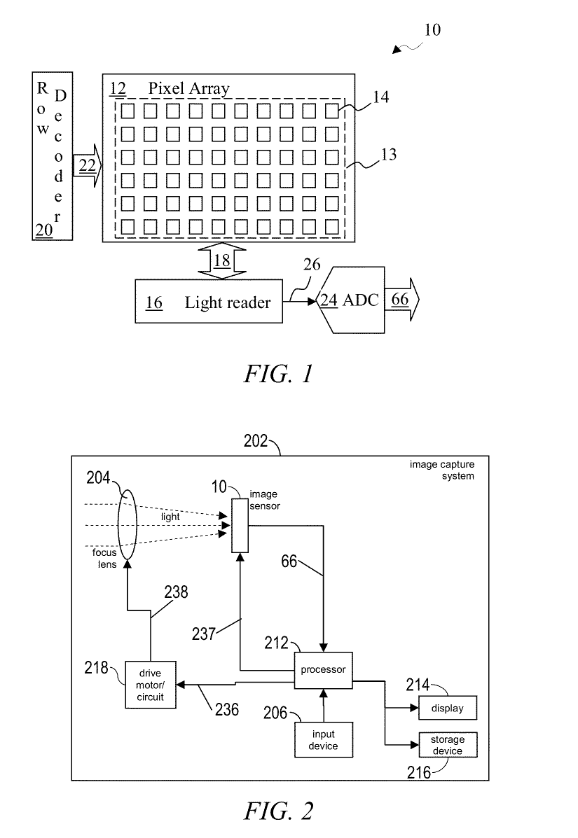

FIG. 1 and FIG. 2 describe an image sensor 10 according to the present invention and an image capture system 202 according to the present invention, respectively.

Referring to the drawings more particularly by reference numbers, FIG. 2 shows an embodiment of an image sensor 10 that comprises a pixel array 12, a row decoder 20, a light reader 16, and an ADC 24. The pixel array 12 is a two dimensional array of pixels 14 of that detect light of different colors, where each pixel has a photoelectric conversion unit. Each pixel has either a color filter that filters light for the intended color of the pixel before the light reaches the photoelectric conversion unit(s) or no color filter where the pixel is configured to detect visible light of any color. Bus 18 comprises column output signal lines that connect pixels by the column. The light reader 16 is a pixel array readout circuit, and may be as described in U.S. Pat. No. 7,233,350 or as described in U.S. patent application Ser. No. 12/639,941. It has one or more capacitor(s) for sampling each column output signal of the bus 18. Analog output signal(s) 26 from the light reader 16 is provided to ADC 24 for conversion into digital image data that are output onto bus 66. The digital image data are mosaic image data in the sense that each pixel does not have all the color components required to represent the color gamut of the visible light spectrum. Row decoder 20 provides row signals in bus 22 for selecting pixels by the row, for resetting pixels by the row, and for transferring charges in pixels by the row. Color filter array 13 is a two-dimensional array of color filters that overlay photoelectric conversion units of the pixel array 12.

FIG. 2 shows an embodiment of an image capture system 202 that includes the image sensor 10, a focus lens 204 that focuses light from a scene onto the pixel array 12, a drive motor and circuit 218 to move the focus lens 204, a processor 212 that receives mosaic images from the pixel array 12 and interpolates them to become color images, an input device 206 for receiving instruction from a user, a display 214 for displaying a down-sampled version of the color images, and a storage device 216 for storing the color images.

### Pixel Array

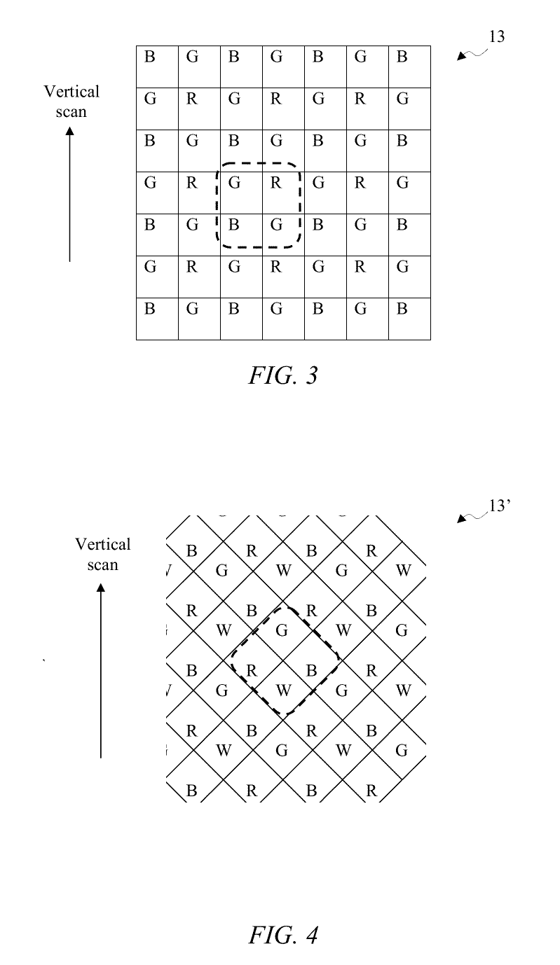

FIGS. 3 to 5 are illustrations showing color filter arrays according to the present invention.

FIG. 3 shows a conventional Bayer patterned color filter array 13. Image output from the pixel array 12 begins at the bottom and progresses to the top, in the direction indicated by the “Vertical Scan” arrow. The color filter array 13 is organized as a two-dimensional array of color filters of Green (G), Red (R), and blue (B) colors. More particularly, the color filter array 13 is organized as a two-dimensional array of a two-by-two subarray (in dashed line) that consists of a pair of green (G) color filters disposed along one diagonal and a pair of a red (R) color filter and a blue (B) color filter disposed along the other diagonal. As a modification, the color filter array 13 may be rotated 45 degrees from what is shown in FIG. 3.

FIG. 4 shows color filter array 13′ as an alternative embodiment of color filter array used in the present invention. It is organized as a two-dimensional array of a two-by-two subarray (in dashed line) that consists of a pair of a green (G) color filter and a white (W) color filter disposed along one diagonal and a pair of a Red (R) color filter and a blue (B) color filter disposed along the other diagonal. As a modification, the color filter array 13′ may be rotated 45 degrees from what is shown in FIG. 4.

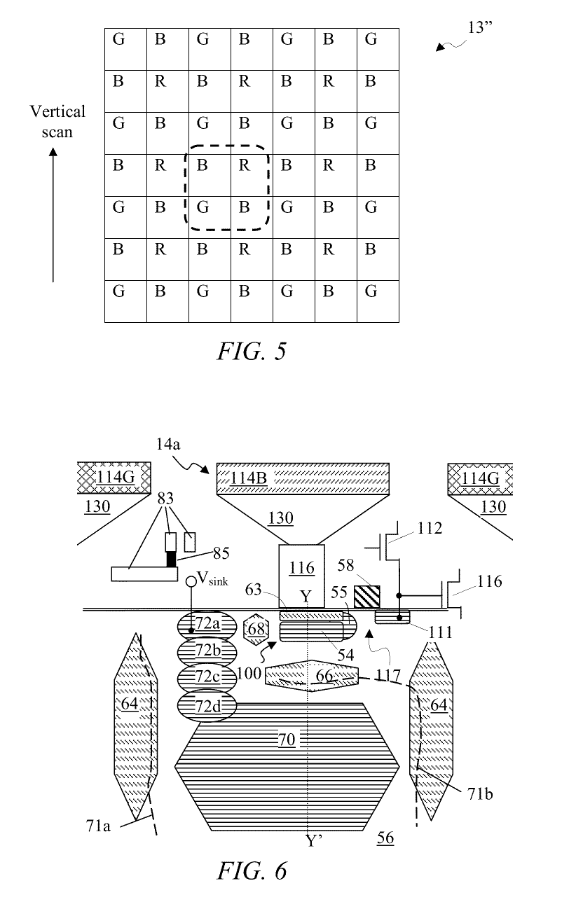

FIG. 5 shows color filter array 13″ as another alternative embodiment of color filter array used in the present invention. It is organized as a two-dimensional array of a two-by-two subarray (in dashed line) that consists of a pair of a blue (G) color filters disposed along one diagonal and a pair of a red (R) color filter and a green (B) color filter disposed along the other diagonal. As a modification, the color filter array 13″ may be rotated 45 degrees from what is shown in FIG. 5.

### Blue Pixel

FIG. 6 shows a vertical section of an embodiment of the blue pixel 14a. It includes a photodiode 100 under a blue color filter 114B. Incident light enters the blue color filter 114B from above, and filtered light is transmitted by upper light guide 130 and subsequently lower light guide 116 to reach the photodiode 100. The photodiode 100 is embedded in a substrate 56 of a first conductivity type, preferably p-type. The substrate 56 may be a lightly doped p-epi layer, doped with boron to the concentration between 1e14/cm³ to 1e16/cm³, on top of a far more heavily doped p-substrate, which can have doping concentration in excess of 1e19/cm³. The photodiode 100 comprises a doped region 54 of a second conductivity type, preferably n-type. The doped region 54 may be doped with phosphorus. It may have an impurity concentration that peaks between 3e16/cm³ and 1e18/cm³. It may be disposed under a surface diffusion layer 63 of the first conductivity type to prevent any depletion layer that extends from the doped region 54 from reaching a top interface of the substrate 56. Adjacent to the doped region 54 is a transfer transistor 117, which has a gate 58, and a drain diffusion 111 of the second conductivity type. A connection region 55 of the second conductivity type may be disposed to bridge the doped region 54 to the transfer transistor 117. During an interval of exposure to light (charge integration period), charges are integrated in the doped region 54. At the end of the charge integration period, charges are transferred from the doped region 54 through the connection region 55 and across the transfer transistor 117 to the drain diffusion 111, resulting in a gate voltage change of output transistor 116, which in turn drives an output voltage along an output signal line (not shown) that is part of the bus 18 to be sampled by the light reader circuit 16. According to the conventional correlated double sampling method, the drain diffusion 111 may be reset by reset transistor 112 immediately prior to the above charge transfer from the photodiode 100 so that a reset output voltage is transmitted by the output transistor 116 along the output signal line and sampled by the light reader circuit 16, and this sampled reset output signal is mutually subtracted with the aforementioned sampled output voltage signal that arises from photodiode charges to result in a de-noised signal, which is subsequently converted to digital signal 66 by the analog-to-digital converter (ADC) 24. Alternative methods of generating de-noised signals may be employed, such as those disclosed in U.S. patent application Ser. No. 12/639,941 and those disclosed in U.S. Pat. No. 7,612,817, whose descriptions of generation of de-noised signals are incorporated herein.

The doped region 54 preferably reaches a depth of between 0.4 um to 1.2 um.

Adjacent to the blue color filter 114B are color filters of other color(s) 114G for adjacent pixels of the other color(s). Conducting interconnect wires 83 and via 85 are embedded in an insulating layer (not shown) between the light guides of adjacent pixels.

A trap region 70 of the second conductivity type is disposed below the doped region. The trap region 70 preferably begins from a depth of between 1.7 um and 2.5 um. It serves to trap stray charges in the substrate 56. For example, red light that penetrates to more than 2 μm into the substrate 56 can release free charge carriers, which are electrons where the first conductivity type is p-type, that diffuse laterally to adjacent pixels or even farther, causing blurriness of the color image and incorrect color detection and reproduction. The trap region 70 helps to trap such stray electron and improve picture sharpness and better colors. During the charge integration period of the photodiode 100, charges freed by blue light received from the blue color filter 114B are collected by the doped region 54. At the same time, stray charges are collected by the trap region 70. These collected stray charges are removed to a surface of the substrate 56 through a connection region of the second conductivity type in the substrate 56, and subsequently removed to terminal Vsink connected to the uppermost connection region 72a. In FIG. 6, a number of connection regions 72a to 72d of the second conductivity type connect the trap region 70 to the top surface of the substrate 56. Other structures known in the semiconductor industry for making electrical connection to a depth of more than 1 μm in the substrate may be employed instead for the connection region. One example being a vertical trench lined filled with polysilicon of the second conductivity type.

The doped region 54 collects charges generated by blue light transmitted from the blue color filter 14a during a charge integration period of the blue pixel. Charges from the doped region 54 are subsequently transferred across the transfer transistor 117 to the drain diffusion 111 to cause a voltage change on the gate of output transistor 116. As a result of the gate voltage change, a corresponding output signal is transmitted along the aforementioned output signal line within the bus 18 to the light reader circuit 16 to be sampled. The sampled signal is used in generating a color image. On the other hand, no charges collected by the trap region 70 is used to generate a signal to be used in the generating of the color image.

The trap region may have an impurity concentration that peaks between 3e16/cm³ and 5e17/cm³. Where the substrate 56 is p-type, the trap region may be doped with phosphorus.

Barrier regions 64 of the first conductivity type may be disposed laterally adjacent to the trap region 70 and connection regions 72a to 72d to stop depletion regions that extend from the latter from extending further laterally.

Additional barrier regions 66, 68 may be disposed between the trap region 70 and the connection regions 72a to 72d, respectively, and the doped region 54 to stop depletion regions that extend from the trap region 70 and the connection regions 72a to 72d, respectively from merging with a depletion region that extends from the doped region 54. A neutral region in each of the barrier regions 66, 68 is sandwiched between the depletion that extends from the trap region 70 (or connection regions 72a to 72d) and the depletion region that extends from the doped region 54.

Dashed lines 71a, 71b shows boundaries of depletion regions that extend from the trap region 70 and the connection regions 72a-72d.

These barrier regions 64, 66, 68 have may have doping concentration may peak between 1e16/cm³ to 5e17/cm³. Where the substrate is p-type, they may be doped with boron.

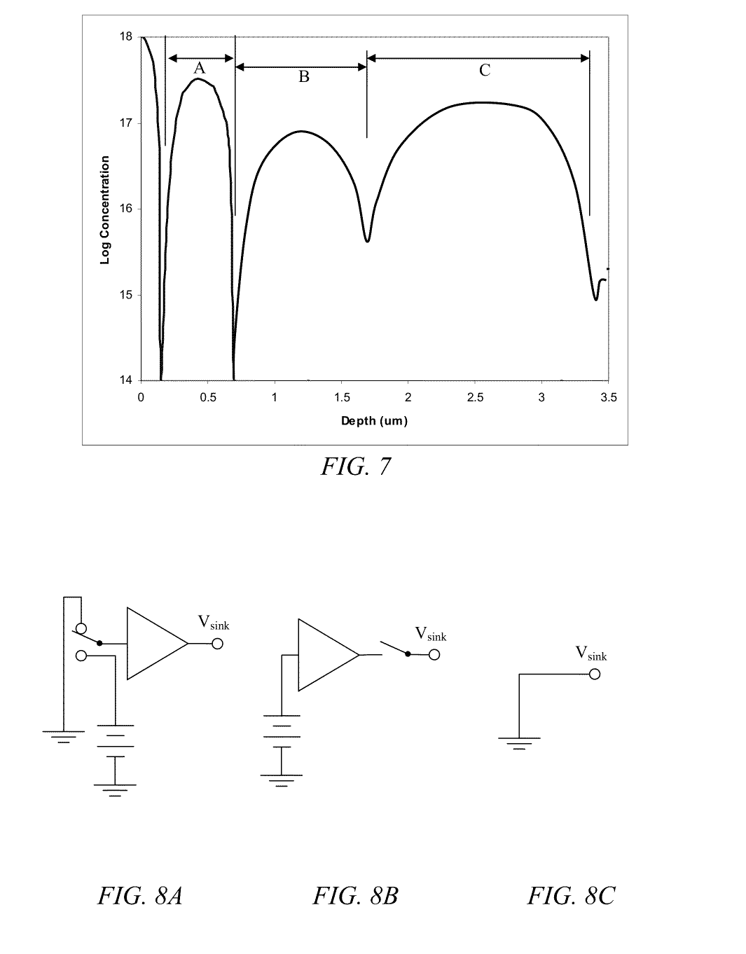

FIG. 7 is a graph that shows a vertical profile of net doping concentration along the vertical cut line YY′ shown in FIG. 6 that cuts through the doped region 54, the barrier region 66, and the trap region 70. “A” labels net doping concentration of the doped region 54. “B” is of the barrier region 66. “C” is of the trap region 70.

FIG. 8A, 8B, 8C show three example configurations for draining stray charges from the terminal Vₛᵢₙₖ. FIG. 8A shows the Vₛᵢₙₖ terminal being driven by a buffer that switches its input source between a ground and a voltage source, where the voltage source may provide a adjustable voltage level. FIG. 8B shows the Vₛᵢₙₖ terminal being driven by a buffer through a switch and the buffer buffers a voltage source. FIG. 8C shows the Vₛᵢₙₖ terminal being connected to ground.

The trap region may be biased to a potential during the charge integration period. Charges collected in the trap region may be removed between successive charge integration periods of the blue pixel. Charges collected in the trap region may be removed during the charge integration period.

### Corner Regions

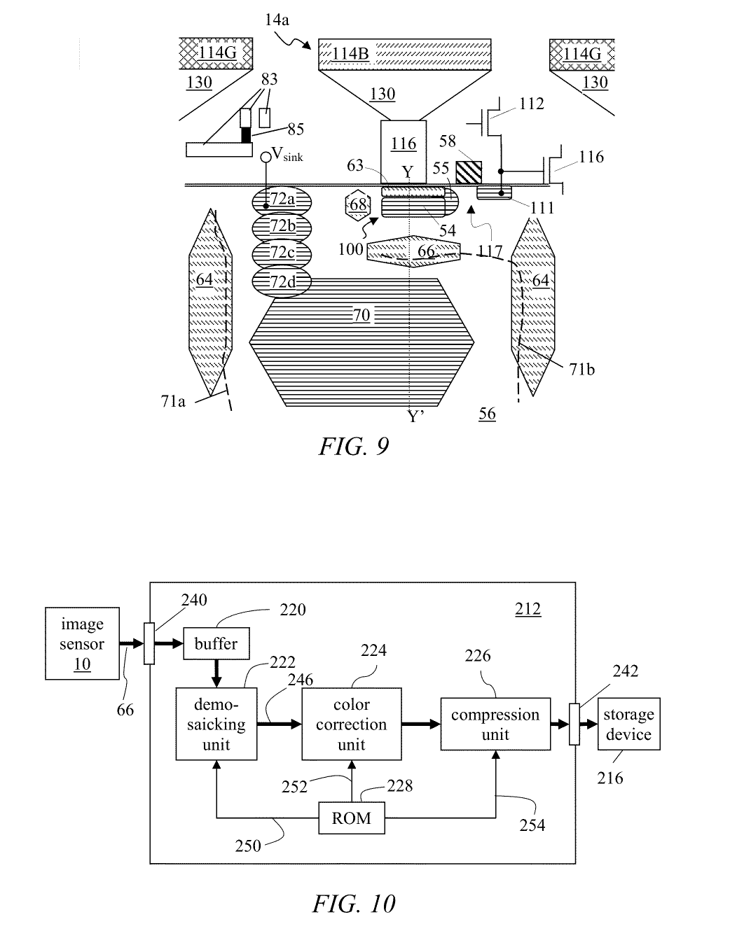

FIG. 9 shown how a blue pixel in a corner region may be modified from that shown in FIG. 6. The trap region may be shifted laterally with respect to the doped region 54.

### Closing Remarks

Although FIG. 10 shows the demosaicking unit 222 being in the processor 212, in an alternate embodiment it may be part of the image sensor 10 and receives digitized image data generated from the pixel array 12 via output bus 66 of the ADC 24 and output the reconstructed full-color image on a different bus.

The demosaicking unit 222 may generate the missing colors. Ultimately, all the generated missing colors are assembled together with the colors in the mosaic image to form a full-color image by color interpolation. The signal generated from charges collected by the doped region 54 during the charge integration period of the blue pixel 14a is used to generate the color image. No signal generated from charges collected by the trap region 70 is used to generate the color image.

Although the reconstructed full-color image is shown to be sent to a color correction unit 224 in FIG. 10, other modifications known in the art may be arranged.

A nonvolatile memory, which may be external to the camera processor 212 or may be part of it, such as the Read-Only Memory (ROM) 228 shown in FIG. 10, may store instructions to cause the demosaicking unit 222 to perform according to any or all of the methods described in this disclosure.

The color filter 114B, 114G may each comprise a different color material, or colorant, such as a dye or a organic or inorganic or organometallic pigment. The color filter may comprise a resin in which the dye is dissolved or the organic or inorganic or organometallic color pigment is suspended, where the resin may be organic or comprise a polymer that has at least an organic group such as methyl, ethyl or phenyl (an example being silicone). Alternatively, the color filter may comprise a transmissive inorganic material (e.g. silicon nitride) having particles of a color pigment (e.g. an inorganic color pigment such as iron oxide, a cobalt or manganese or zinc or copper pigment, or an organometallic pigment, or a complex inorganic color pigment) dispersed therein.

Adjacent color filters exhibit different colors in white light. Preferably, each has a highest transmittance and a least transmittance of at least 50% and at most 10%, respectively, between wavelengths (in air) of 400 nm to 700 nm. Alternatively, a ratio between its highest and least transmittances shall be more than 4-to-1.

Alternatively, any of the color filters may be more generally a color filter means for providing different transmittance to visible light of different colors. Preferably, each has a highest transmittance and a least transmittance of at least 50% and at most 10%, respectively, between wavelengths (in air) of 400 nm to 700 nm. Alternatively, a ratio between its highest and least transmittances shall be more than 4-to-1. The color filter means can be a grating.

In an alternative embodiment for the blue pixel, the uppermost connection region 72a does not reach the upper surface of the substrate 56. Instead, it is under a layer of surface region of the first conductivity type in the substrate. A transistor is provided adjacent to the uppermost connection region 72a to conduct away the stray charges from the uppermost connection region 72a. Such as transistor may be a buried-channel transistor.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. An image sensor pixel array supported by a substrate of a first conductivity type, the image sensor array comprising a plurality of blue pixels interspersed between a plurality of pixels of one or more other colors, each one of the blue pixels comprising:
a blue color filter;
a photoelectric conversion unit that comprises a doped region of a second conductivity type in the substrate, the photoelectric conversion unit being arranged to receive light from the blue color filter; and,
a trap region of the second conductivity type in the substrate and below the doped region,
wherein charges collected by the trap region during a charge integration period of the photoelectric conversion unit are removed to a surface of the substrate.

2. The image sensor pixel array of claim 1, wherein no charges collected by the trap region are used to generate an image generated from charges collected by the photoelectric conversion unit during the charge integration period.

3-7. (canceled)

8. A method of generating a color image using the image sensor pixel array of any one of the above claims, the color image being generated from charges collected by the photoelectric conversion unit during the charge integration period, wherein no charges collected by the trap region is used to generated the color image.

9. The image sensor pixel array of claim 2, wherein the trap region is biased to a potential during the charge integration period.

10. The image sensor pixel array of claim 2, wherein charges collected in the trap region are removed between successive charge integration periods of the photoelectric conversion unit.

11. The image sensor pixel array of claim 2, wherein charges collected in the trap region are removed during a charge integration period of the photoelectric conversion unit.

12. The image sensor pixel array of claim 1, wherein the trap region is biased to a potential during the charge integration period.

13. The image sensor pixel array of claim 1, wherein charges collected in the trap region are removed between successive charge integration periods of the photoelectric conversion unit.

14. The image sensor pixel array of claim 1, wherein charges collected in the trap region are removed during a charge integration period of the photoelectric conversion unit.

15. The image sensor pixel array of any one of the above claim 1, wherein a half of pixels within a rectangular region within the image pixel array are blue pixels.

16. The image sensor pixel array of claim 1, wherein the trap region is laterally shifted with respect to the doped region between a center of the image sensor pixel array to a corner region of the image sensor pixel array.

17. The image sensor pixel array of any one of the above claim 2, wherein a half of pixels within a rectangular region within the image pixel array are blue pixels.

18. The image sensor pixel array of claim 2, wherein the trap region is laterally shifted with respect to the doped region between a center of the image sensor pixel array to a corner region of the image sensor pixel array.

19. The image sensor pixel array of claim 15, wherein the trap region is laterally shifted with respect to the doped region between a center of the image sensor pixel array to a corner region of the image sensor pixel array.

20. The image sensor pixel array of claim 17, wherein the trap region is laterally shifted with respect to the doped region between a center of the image sensor pixel array to a corner region of the image sensor pixel array.
